(19) United States
(12) Patent Application Publication
(10) Pub. No.: US 2009/0108442 A1
(43) Pub. Date: Apr. 30, 2009

(54) SELF-ASSEMBLED STRESS RELIEF INTERFACE

(75) Inventors: John A. Fitzsimmons, Poughkeepsie, NY (US); Mukta G. Farooq, Hopewell Junction, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/923,997

(22) Filed: Oct. 25, 2007

(51) Int. Cl. H01L 23/48; H01L 21/56

(52) U.S. Cl. 257/737; 438/127; 257/E23.01; 257/E21.502

(57) ABSTRACT

A method of forming an interconnect assembly is provided in which contacts exposed at a face of a first element such as, for example, a microelectronic element are aligned and joined with corresponding contacts of an interconnect element confronting the face of the first element. At least one of the i) the contacts of the first element, ii) the corresponding contacts of the interconnect element, iii) a joining metal between the contacts and the corresponding contacts includes a catalyst metal. Subsequently, a material including an organic component contacting the catalyst metal reacts to form volume expansion accommodation elements in the presence of the catalyst metal, the reaction being limited by proximity with the catalyst metal, such that the interconnect assembly includes volume expansion accommodation elements adjacent to the joined contacts.

### BACKGROUND OF THE INVENTION

The present invention relates to methods of interconnecting microelectronic elements or microelectromechanical (MEM) elements, e.g., semiconductor chips, integrated circuits and the like and assemblies including semiconductor chips.

Microelectronic elements, e.g., semiconductor chips, require packaging before they can be incorporated into larger electronic systems. In most cases, semiconductor chips cannot be connected directly to circuit panels, e.g., printed wiring boards, due to electrical reasons, mechanical reasons, or both. Chips require packaging for electrical reasons when the contacts on the chip are too densely packed and too numerous to connect directly to a circuit panel. Packaging may also be required to minimize inductance and capacitance along signal paths to and from a chip. Chips also require packaging for mechanical reasons, due to differences in the materials from which a chip and a printed wiring board typically are made. Because of the differences in materials, when the chip heats up during operation, a chip carrier or substrate to which the chip is connected typically expands at a faster rate than the chip. The chip carrier expands faster because it has a coefficient of thermal expansion (“CTE”) which is higher than that of the chip.

This problem of one element expanding to a different degree than the chip, called “thermal expansion mismatch”, needs to be managed so that the semiconductor chip performs reliably over its entire lifetime. This is especially important for some chips such as processor chips which experience temperature rises during operation of 100° C. or more. With reference to FIG. 1A, in a flip-chip package 10, solder bumps 18 are used to mount a semiconductor chip 12 to a chip carrier 14 or substrate. In order to lessen thermal expansion mismatch, the chip carrier or substrate can be made from a material having a coefficient of thermal expansion at or close to that of the chip. Such chip carriers or substrates, typically made of glass or ceramic materials, can be expensive to make and harder to work with. Other chip carriers which include polymeric dielectric layers, such as polyimide, for example, are less expensive and may be easier to use, but have a CTE higher than that of semiconductor chips. For example, while silicon has a CTE of 3.5 parts per million per degree C (ppm/° C.), polyimide typically has a CTE of about 12 to 15 ppm/° C. In such case, the package must be designed to cope with the stresses due to thermal expansion mismatch between the chip and chip carrier which are unavoidable due to the difference between the semiconductor material of the chip and that of the polymeric dielectric layer. In addition, the package must be designed to accommodate thermal expansion of the soldered joints themselves.

Sometimes, an underfill 16 is provided as a layer helping to stiffen the interface between the front face 20 of the chip 12 and the chip carrier 14. The underfill limits the movement of the chip relative to the chip carrier 14. As illustrated in FIG. 1B, the underfill typically fills all the space between the front face 18 of the chip and the chip carrier 14, and surrounds each solder bump 18 individually. The underfill, as well as the material of which the chip carrier is constructed, help manage the stresses in the package due to thermal expansion mismatch.

Traditionally, lead and tin are alloyed together to form a solder. Some solders include a high percentage content of lead, as used in traditional C4 (“controlled collapse chip connect”) packaging and interconnect technology pioneered by International Business Machines Corporation. A high lead content solder used in C4 technology has a melting temperature of about 375° C., which is significantly higher than that of tin at 250° C. Because of this, solder joints are formed at relatively high melting temperatures, allowing subsequent processes to be performed at higher temperatures as well. At operating temperatures of the chip, lead has a comparative advantage over tin in that lead is softer than tin and yields to stresses more than tin. Generally, packaged chips which include high lead content solder joints are well-suited to withstanding stresses due to thermal expansion mismatch.

However, recent industry developments are requiring changes in the ways that microelectronic elements are packaged and externally interconnected. For various reasons, lead-free solders are required in applications where until now lead-containing solders had been used. Lead-free solders usually have much greater amounts of tin. Tin does not yield to stress as much as lead, such that the solder bumps formed of tin-based solder can delaminate from their attachment points more readily than lead. Moreover, because they yield less to stress, tin-based solder bumps tend to transfer stress to the chip or the chip carrier more readily than lead-based solder bumps.

Some efforts at managing thermal expansion mismatch have involved the use of ceramic, glass or other materials having a coefficient of thermal expansion (“CTE”) close to that of the semiconductor chip packaged therewith.

In some cases, a complex underfill structure is provided. For example, as described in commonly owned United States Patent Publication No. 2006/0040567, a compressible film is deposited and photolithographically patterned to surround solder connectors extending above a surface of an element, e.g., a chip. Subsequently, the chip is joined with another element such as a carrier and the solder connectors are reflowed to form joints connecting the chip with the carrier. An underfill can then be inserted into the remaining space between the chip and the carrier.

For various reasons, solder alloys including amounts of certain metals such as silver, copper, gold, platinum, palladium, chromium, titanium, nickel, copper, aluminum and zirconium have been proposed, as described in United States Patent Publication Nos. 2006/0027632, 2005/0127143 and 2005/0133572 and U.S. Pat. No. 6,659,329. The forming of solder-wettable conductive pads on chips to include one or more of such metals is described in U.S. Pat. No. 6,917,106. However, none describes the use or desirability to use such metal to form elements that accommodate expansion within an interconnect assembly such as a package containing a chip.

U.S. Pat. No. 7,108,914 describes a flip-chip package which has a self-healing underfill layer incorporating microcapsules of polymerizable material. In the event the underfill layer becomes damaged due to cracking, microcapsules along the crack open, the material within spills outs and then polymerizes to repair the damage. Here again, there is no use of a metal to form elements that accommodate expansion within an interconnect assembly such as a package containing a chip.

It would be desirable to provide processes and packages, e.g., packages containing one or more chips which are suitable for use in a variety of applications. It would be desirable to provide chip packages which are suitable for use in high thermal stress applications, among others, without requiring high lead content solders to be used. It would further be desirable to provide packages which can withstand high thermal stress, without requiring multiple different underfill regions to be formed by photolithography before the chip is attached to a chip carrier.

### SUMMARY OF THE INVENTION

A current need exists to improve flip-chip packaged microelectronic elements and processes for producing them. Particularly in the context of flip-chip packaged microelectronic elements incorporating a chip carrier which is not thermally matched with the microelectronic element, e.g., a chip carrier consisting primarily of a polymer such as polyimide, a current need exists to produce packages which can better withstand thermal stress. Packages which incorporate lead-free solders can especially benefit in accordance with embodiments of the invention shown and described herein.

According to an aspect of the invention, a method of forming an interconnect assembly is provided. In such method, contacts exposed at a face of a first element are aligned and joined with corresponding contacts of an interconnect element confronting the face of the first element, wherein i) the contacts of the first element, ii) the corresponding contacts of the interconnect element, iii) a joining metal between the contacts and the corresponding contacts, or iv) more than one of i), ii) or iii) includes a catalyst metal. Subsequently, a material including an organic component contacting the catalyst metal is caused to react and form volume expansion accommodation elements in the presence of the catalyst metal, the reaction being limited by proximity with the catalyst metal, such that the interconnect assembly includes volume expansion accommodation elements are adjacent to the joined contacts.

According to another aspect of the invention, an assembly is provided in which a first element has a face and contacts exposed at the face. The assembly includes an interconnect element which has corresponding contacts joined with the contacts of the first element. A plurality of volume expansion accommodation elements which include a reaction product of an organic material are disposed immediately adjacent to at least individual ones of the joined contacts. In addition, the contacts of the first element, ii) the corresponding contacts of the interconnect element, iii) a joining metal between the contacts and the corresponding contacts, or iv) more than one of i), ii) or iii) includes a catalyst metal which is capable of assisting a reaction of the organic material to form the volume expansion accommodation elements.

### BRIEF DESCRIPTION OF THE DRAWINGS

FIG. 1A is a sectional view and FIG. 1A is a corresponding plan view illustrating a packaged microelectronic element in accordance with the prior art.

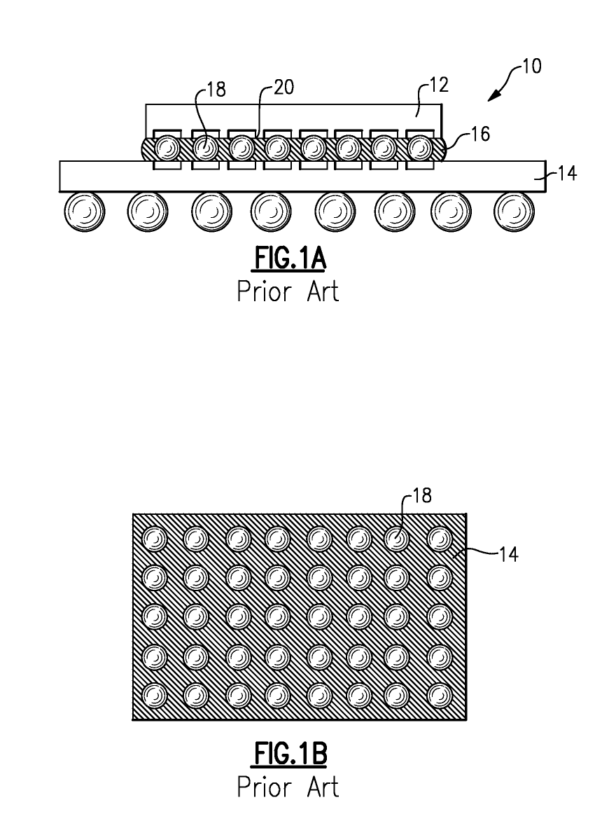

FIG. 2A is a sectional view and FIG. 2B is a corresponding plan view illustrating a preliminary stage in a method of fabricating a packaged microelectronic element in accordance with an embodiment of the invention.

FIG. 3A is a sectional view and FIG. 3B is a corresponding plan view illustrating a stage in a method of fabricating a packaged microelectronic element subsequent to the stage illustrated in FIGS. 2A-B.

FIG. 4A is a sectional view and FIG. 4B is a corresponding plan view illustrating a stage in a method of fabricating a packaged microelectronic element subsequent to the stage illustrated in FIGS. 3A-B.

FIG. 5A is a sectional view and FIG. 5B is a corresponding plan view illustrating a stage in a method of fabricating a packaged microelectronic element subsequent to the stage illustrated in FIGS. 4A-B.

### DETAILED DESCRIPTION

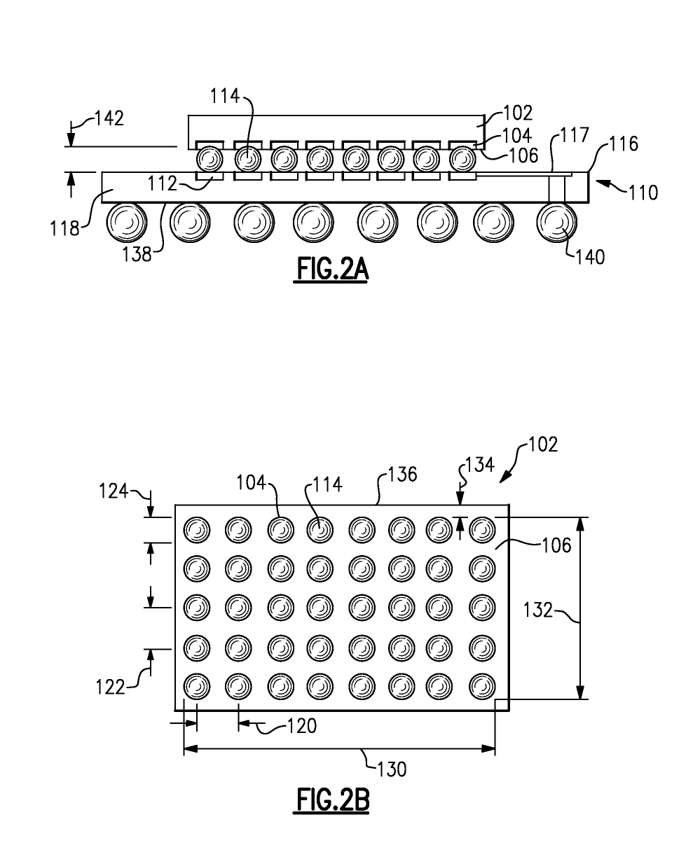

With reference to FIGS. 2A-2B, a method is provided for fabricating a packaged microelectronic element in accordance with an embodiment of the invention. FIG. 2A illustrates a microelectronic element 102, e.g., semiconductor chip, MEMs chip, and the like, having contacts 104 exposed at a front face 106 thereof. The microelectronic element 102 can include a semiconductor chip, e.g., one containing a semiconductor region including silicon, germanium, another Group IV element such as carbon or combination thereof. Alternatively, the semiconductor region can include one or more Group III-V semiconductor compounds of a Group III element of the periodic table with a Group V element, among which are gallium arsenide, indium phosphide, or others, or one or more compound semiconductors including a compound of a Group II element of the periodic table with a Group VI element. FIG. 2B is a plan view illustrating one possible way in which contacts 104 at the face 106 of the chip 102 can be arranged. In the grid arrangement shown, contacts 104 are disposed at a regular horizontal pitch 120 in a horizontal direction along the front face 106 of the chip, and are disposed at a regular vertical pitch 122 in a vertical direction along the front face 106 of the chip. The horizontal pitch can be the same as the vertical pitch but need not be. In one example, the pitch can range from 100 μm to 250 μm. The contacts 104 of the chip are joined to corresponding contacts 112 of an interconnect element 110 through conductive features 114, e.g., solder masses, other types of conductive features or combination thereof. The connecting element can have any suitable shape, e.g., ball, column or barrel shape. Each conductive feature, e.g., each solder mass, has a diameter which in one example can range from about 50 μm to about 100 μm. In a particular example, the contacts 104 of the chip have solder bumps 114 joined thereto and are arranged in grid fashion which can be referred to as a ball grid array (“BGA”). The ball grid array has a vertical dimension 132 extending in a vertical layout direction and a horizontal dimension 130 extending in a horizontal layout direction. In one example, each of the vertical and horizontal dimensions 130, 132 of the ball grid array can range from a few millimeters to tens of millimeters. The solder bumps 114 may be disposed close to edges of the chip, such that a spacing 134 of perhaps only 100-200 μm may be present between an edge of a solder bump and the adjacent edge 136 of the chip.

The solder bumps 114 are conductively interconnected with contacts 112 exposed at a top surface 116 of the interconnect element. In one embodiment, the interconnect element includes a dielectric element 118 having a top surface 116 at which the contacts 112 are exposed. A plurality of external conductive bumps or other terminals 140 are exposed at or below a bottom surface 138 of the dielectric element 118 for use in providing conductive interconnection between the interconnect element 118 and another element such as a circuit panel. Traces 117 may extend along the dielectric element 118 for connecting the contacts 112 with the terminals 140. As depicted in FIG. 2A, trace 117 extends along the top surface 116 of the dielectric element 118.

The dielectric element of the interconnect element can be of various types, consisting essentially of material, such as, for example, silicon, ceramic, carbon-doped glass, or a laminate material. In another example, the dielectric element can include an organic material such as a layer of polyimide or other polymeric material having a relatively low CTE of between about 10 and 20 ppm/° C.

As further shown in FIG. 2A the chip 102 can be disposed at a very close spacing to the interconnect element, such that the distance between a dielectric passivation layer (not shown) at the front face 106 of the chip and the top surface 116 of the interconnect element can range from 50 to 200 μm, depending on the diameter of the solder bumps 114.

After forming the structure illustrated in FIGS. 2A-B, steps are now conducted to form volume expansion accommodation elements which will assist in relieving stresses present in the soldered joints which interconnect the contacts of the chip with the contacts of the interconnect element. As will be understood from the discussion below, these elements, which can be referred to as “expansion elements” are coaxially aligned with each solder bump and are designed to yield to stresses within the package such as due to thermal expansion mismatch. The expansion elements can help relieve stresses whether or not an underfill is also provided between the chip and the interconnect element. In one example, an underfill layer is used to stiffen the interface between the front face of the chip and the interconnect element, reducing movement between them when temperature increases such as during operation. A consequence of the reduced movement is increased stress borne by each solder bump. In such example, the expansion elements can be used to relieve stresses on each solder bump by allowing greater expansion and contraction in the immediate vicinity of each bump. The expansion elements accommodate an expansion in the volume of each solder bump to a much greater extent than the underfill. In addition, because the expansion elements do not occupy the entire space between adjacent solder bumps connecting the chip and the interconnect element, an underfill can still be provided within the remaining space. In such way, the packaged chip can benefit from the stiffened interface provided through an underfill while stresses present at each solder bump are relieved by the expansion elements.

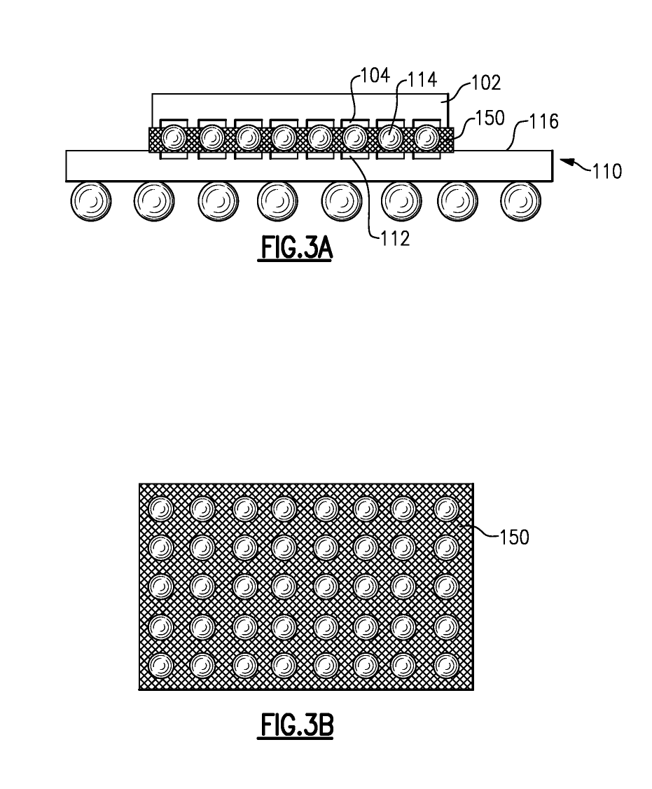

With reference to FIGS. 3A-B, in accordance with an embodiment of the invention, the expansion elements are formed by a self-assembly process. A material 150 is inserted between front face 106 of the chip and the confronting top surface 116 of the interconnect element such that the material contacts the solder bumps 114 and may also touch the contacts 104 of the chip and the corresponding contacts 112 of the interconnect element. The material may be inserted such that it fills the entire space in and around each solder bump between the chip 102 and the interconnect element 110. The expansion elements then form in contact with one or more of the solder bumps 114, the contacts 104, or contacts 112 by reaction of the inserted material in the presence of a catalyst metal exposed at a surface of one or more of the bumps 114, the contacts 104 or contacts 112. The reaction can be controlled by appropriate control over temperature, time and ambient conditions, e.g., presence or absence of gases in a controlled environment.

In one embodiment, the material can be provided as a gel containing an oligomer having a low molecular weight. The gel can include one or more precursors to polymers such as, for example, silicone elastomers, olefinic block co-polymers, elastomeric polypropylenes, polymeric styrenes, polycarbonates, polyethylene terpinphthalate (“PET”), poly phenylene oxide (“PPO”), and neoprenes. A reaction occurs, assisted by the catalyst metal, in which such precursor material cross links to form the resulting polymer. Such reaction can be catalyzed by a variety of metals. In one example, one or more of the solder bumps 114, contacts 104 of the chip, or the contacts 112 of the interconnect element includes a catalyst metal such as, for example, a platinum group metal, silver, chromium, nickel, titanium, aluminum and zirconium.

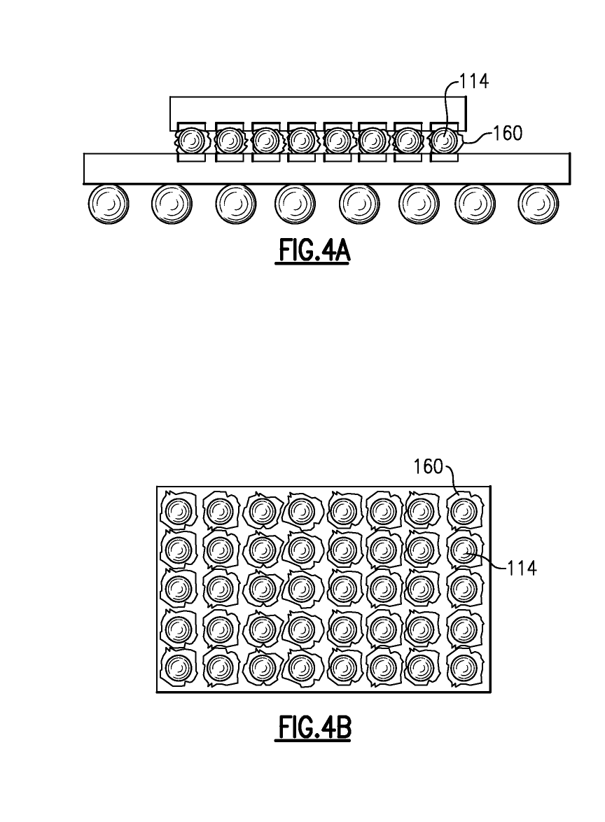

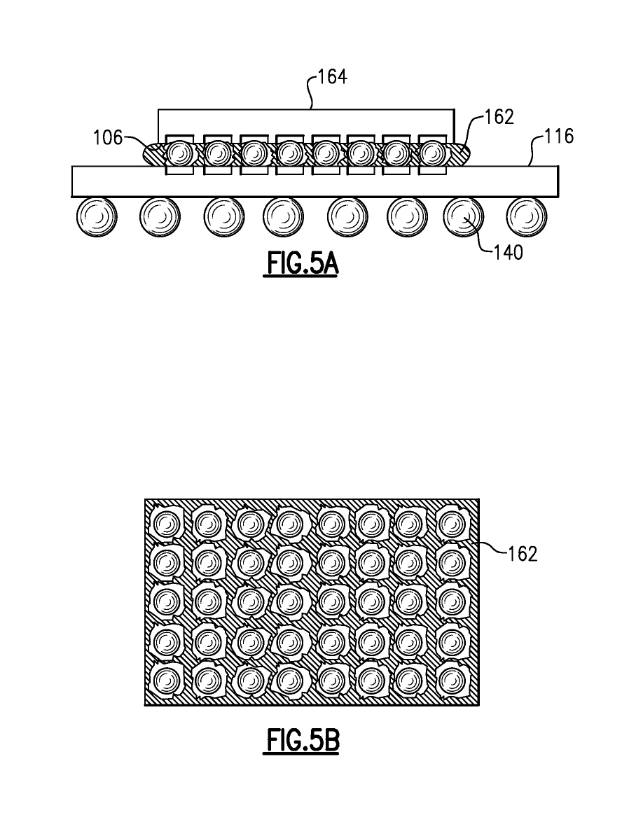

After the expansion elements have been formed by such reaction, unreacted portions of the material can then be removed, such that the expansion elements 160 (FIGS. 4A-B) remain in place contacting or surrounding each solder bump 114. The unreacted material can be removed using a solvent, e.g., a solution containing a surfactant, alcohol, photoresist developer, or combination thereof, for example. Subsequently, as illustrated in FIGS. 5A and 5B, an underfill 162 can be formed in the space between the front face 106 of the chip and the top surface 116 of the interconnect element. The underfill increases the rigidity of the package, substantially stiffening the interface between the chip and the interconnect element. With the expansion elements in place, an underfill can be selected which forms a substantially rigid interface within the package. In a particular embodiment, the material of the expansion elements 160 (FIG. 4A) has a modulus of elasticity (Young's modulus) with a lower value than the modulus of elasticity of the underfill material 162, making the material of the expansion elements more easily compressed than the underfill material. Stated another way, the underfill material imparts substantial rigidity to the packaged chip, while the expansion elements accommodate a relatively greater amount of expansion of the fusible metal, e.g., solder, in the joints connecting the chip to the interconnection element, e.g., substrate.

After forming the underfill, additional steps can be performed as necessary to complete the package. For example, a metallic thermal conductor (not shown) having fins can be attached to the rear surface 164 for dissipating heat arising from operation of the chip. In another example, an overmold (not shown) can be formed over the rear surface of the chip and an exposed portion of the top surface 116 of the interconnect element.

In a variation of the above-described method, the interconnect element can be attached to the chip before the exterior contacts 140 are formed thereon. For example, when the exterior contacts include a low melting temperature solder, they can be formed after other processing steps, for example, after the expansion elements and the underfill are formed. The exterior contacts can be formed by aligning low melting temperature solder balls thereto and elevating the temperature until the solder balls melt and become attached to the interconnect element.

While the invention has been described in accordance with certain preferred embodiments thereof, many modifications and enhancements can be made thereto without departing from the true scope and spirit of the invention, which is limited only by the claims appended below.

What is claimed is:

1. A method of forming an interconnect assembly, comprising:
a) aligning and joining contacts exposed at a face of a first element with corresponding contacts of an interconnect element confronting the face of the first element, wherein i) the contacts of the first element, ii) the corresponding contacts of the interconnect element, iii) a joining metal between the contacts and the corresponding contacts, or iv) more than one of i), ii) or iii) includes a catalyst metal; and
b) causing a material including an organic component contacting the catalyst metal to react and form volume expansion accommodation elements in the presence of the catalyst metal, the reaction being limited by proximity with the catalyst material,
such that the interconnect assembly includes volume expansion accommodation elements adjacent to the joined contacts.

2. The method as claimed in claim 1, wherein step (b) is performed after step (a).

3. The method as claimed in claim 2, wherein step (b) includes inserting the material between the confronting faces of the first element and the interconnect element.

4. The method as claimed in claim 1, further comprising (c) removing an unreacted portion of the material from between the confronting faces of the first element and the interconnect element after step (b).

5. The method as claimed in claim 4, further comprising (d) forming an underfill layer between the face of the first element and the interconnect element after step (c), the underfill layer being spaced from individual ones of the joined contacts by respective ones of the volume expansion accommodation elements.

6. The method as claimed in claim 1, wherein the first element includes a microelectronic element, the method further comprising (c) forming an underfill layer between the face of the microelectronic element and the interconnect element after step (b), the underfill layer being spaced from individual ones of the joined contacts by respective ones of the volume expansion accommodation elements.

7. The method as claimed in claim 6, wherein a modulus of elasticity of the underfill layer has a first value and the modulus of elasticity of the volume expansion accommodation elements has a second value, the second value being substantially lower than the first value.

8. The method as claimed in claim 6, wherein the interconnect element includes a dielectric element and the corresponding contacts of the interconnect element are exposed at a face of the dielectric element.

9. The method as claimed in claim 1, wherein the first element includes a dielectric element and traces extending from the contacts along a face of the dielectric element.

10. The method as claimed in claim 1, wherein the catalyst metal includes at least one metal selected from the group consisting of a platinum group and silver, chromium, nickel, titanium, aluminum and zirconium.

11. The method as claimed in claim 10, wherein the material includes a material selected from the group consisting essentially of silicone elastomers, olefinic block co-polymers, elastomeric polypropylenes, polymeric styrenes, polycarbonates, polyethylene terpinphthalate (“PET”), poly phenylene oxide (“PPO”), and neoprenes.

12. An assembly, comprising:
a first element having a face and contacts exposed at the face;
an interconnect element having corresponding contacts joined with the contacts of the first element; and
volume expansion accommodation elements coaxially aligned with individual ones of the joined contacts, the volume expansion accommodation elements including a polymeric material having a relatively low modulus of elasticity,
wherein i) the contacts of the first element, ii) the corresponding contacts of the interconnect element, iii) a joining metal between the contacts and the corresponding contacts, or iv) more than one of i), ii) or iii) includes a catalyst metal capable of assisting a reaction of a material to form the polymeric material.

13. The assembly as claimed in claim 12, further comprising an underfll layer disposed between the face of the first element and the interconnect element, the underfill layer being spaced from the individual ones of the joined contacts by respective ones of the volume expansion accommodation elements, the underfill layer having a second modulus of elasticity higher than the modulus of elasticity of the polymeric material.

14. The assembly as claimed in claim 12, wherein the catalyst metal includes at least one metal selected from the group consisting of a platinum group and silver, chromium, nickel, titanium, aluminum and zirconium.

15. The assembly as claimed in claim 14, wherein the polymeric material is selected from the group consisting essentially of silicone elastomers, olefinic block co-polymers, elastomeric polypropylenes, polymeric styrenes, polycarbonates, polyethylene terpinphthalate (“PET”), poly phenylene oxide (“PPO”), and neoprenes.

16. The assembly as claimed in claim 12, wherein the first element includes a microelectronic element, the assembly further comprising an underfill layer disposed between the face of the first element and the interconnect element, the underfill layer being spaced from individual ones of the joined contacts by respective ones of the volume expansion accommodation elements.

17. The assembly as claimed in claim 12, wherein the interconnect element includes a dielectric element, the corresponding contacts being exposed at a face of the dielectric element confronting the face of the microelectronic element.

18. The assembly as claimed in claim 12, wherein the first element includes a dielectric element and traces extending from the contacts along a face of the dielectric element.
